(19) United States
(12) Patent Application Publication
(10) Pub. No.: US 2023/0393208 A1
(43) Pub. Date: Dec. 7, 2023

(54) SYSTEM AND METHOD OF ESTIMATING RESULT OF ENDURANCE TEST ON FUEL CELL SYSTEM

(71) Applicant: TOYOTA JIDOSHA KABUSHIKI KAISHA, Toyota-shi (JP)

(72) Inventors: Keiji KISHIDA, Toyoake-shi (JP); Koichiro YAMASHITA, Seto-shi (JP)

(21) Appl. No.: 18/315,522

(22) Filed: May 11, 2023

(30) Foreign Application Priority Data
Jun. 6, 2022 (JP) 2022-091535

(51) Int. Cl. G01R 31/378; G01R 31/382

(52) U.S. Cl. CPC G01R 31/378; G01R 31/382

(57) ABSTRACT

A system includes a first storage unit configured to store a result of an endurance test actually carried out over a first period under a first use condition as training data, and a first arithmetic unit having a machine learning model configured to perform machine learning using the training data stored in the first storage unit. The machine learning model is configured to estimate a result when the endurance test is carried out under a second use condition. The first use condition is a use condition in which a predetermined operation parameter that influences degradation of the fuel cell system appears with equal frequency over an entire domain of the operation parameter. The second use condition is a use condition in which the operation parameter appears with unequal frequency in at least part of the domain of the operation parameter.

### CROSS-REFERENCE TO RELATED APPLICATION

This application claims priority to Japanese Patent Application No. 2022-091535 filed on Jun. 6, 2022, incorporated herein by reference in its entirety.

### BACKGROUND

### 1. Technical Field

The disclosure relates to a system and a method of estimating a result of an endurance test on a fuel cell system.

### 2. Description of Related Art

Japanese Unexamined Patent Application Publication No. 2020-162309 (JP 2020-162309 A) describes a technology to reuse a battery mounted on a vehicle, in another product. In this technology, both operational data of a battery before reuse and operational data of the battery after reuse are collected, and a machine learning model that estimates the durability (service life) of the battery is created by performing machine learning using the collected operational data as training data.

### SUMMARY

Generally, for example, before a new product of a vehicle or the like is introduced to the public, an endurance test needs to be carried out beforehand on a fuel cell system mounted on the vehicle. However, if the endurance test is carried out until the service life of the fuel cell system, enormous time needs to be consumed. It is conceivable to estimate the durability of a fuel cell system by using an estimation model subjected to machine learning as described in JP 2020-162309 A as one of methods of solving the above task.

However, even for the same fuel cell system, a use condition that the fuel cell system experiences varies in accordance with the type and use of a vehicle on which the fuel cell system is mounted. In other words, there are various operation parameters (for example, a rate of change in current, a rate of change in voltage, ambient temperature, and the like) in a fuel cell system, and the range and the appearance frequency of possible values of each operation parameter vary in accordance with the type and use of a vehicle on which the fuel cell system is mounted. These operation parameters influence the degradation of the fuel cell system. Therefore, in an existing idea, an estimation model subjected to machine learning needs to be individually prepared in accordance with a use condition that a fuel cell system experiences (for example, the type and use of a vehicle on which a fuel cell system is mounted).

The disclosure provides a technology capable of estimating the durability of a fuel cell system regardless of a use condition that the fuel cell system experiences.

A first aspect of the disclosure is implemented as a system of estimating a result of an endurance test on a fuel cell system. The system may include a first storage unit configured to store a result of the endurance test actually carried out over a first period under a first use condition as training data, and a first arithmetic unit having a machine learning model configured to perform machine learning using the training data stored in the first storage unit. The machine learning model is configured to estimate a result when the endurance test is carried out under a second use condition. In this case, the first use condition may be a use condition in which a predetermined operation parameter that influences degradation of the fuel cell system appears with equal frequency over an entire domain of the operation parameter. The second use condition may be a use condition in which the operation parameter appears with unequal frequency in at least part of the domain.

In the above system, a result of the endurance test actually carried out under the first use condition is stored as training data. Then, by performing machine learning using the training data, the machine learning model configured to estimate the durability of (more specifically, the result of the endurance test on) the fuel cell system under the second use condition is created. Under the first use condition, a predetermined operation parameter that influences degradation of the fuel cell system appears with equal frequency over an entire domain of the operation parameter. By using such a result of a non-biased endurance test, a high general-purpose machine learning model widely compatible even under various use conditions is prepared. Thus, regardless of the details of the second use condition, that is, regardless of a use condition that the fuel cell system experiences, the durability of the fuel cell system is estimated.

In the first aspect, the system may further include a second storage unit configured to store a result of the endurance test actually carried out over a second period shorter than the first period under a second use condition as first evaluation data, and a second arithmetic unit configured to evaluate a result shorter than or equal to the second period, estimated by the first arithmetic unit, by comparing the result with the first evaluation data stored in the second storage unit. When the above evaluation by comparison is performed, for example, a user is able to objectively ensure the validity of estimation made by the system. If the reliability is lower than a reference value, training may be performed by using a result of an actual endurance test under the second use condition, and the first arithmetic unit may be caused to correct the machine learning model.

In the above configuration, the second storage unit may be further configured to store a result of the endurance test actually carried out over the first period under a third use condition as second evaluation data, the first arithmetic unit may be further configured to estimate a result when the endurance test has been carried out for longer than or equal to the second period under the third use condition, by using the second evaluation data stored in the second storage unit, and the second arithmetic unit may be further configured to evaluate the result under the third use condition, estimated by the first arithmetic unit, by comparing the result with the second evaluation data stored in the second storage unit. When the above evaluation by comparison is performed, for example, a user is able to objectively ensure the validity of estimation made by the system. If the estimation accuracy is lower than a reference value, training may be performed by using a result of an actual endurance test under the third use condition, and the first arithmetic unit may be caused to correct the machine learning model.

In the above configuration, the second storage unit may be further configured to store a result of the endurance test actually carried out over the second period under a fourth use condition as third evaluation data, the first arithmetic unit may be further configured to estimate a result when the endurance test has been carried out for shorter than or equal to the second period under the fourth use condition, by using the third evaluation data stored in the second storage unit, and the second arithmetic unit may be further configured to evaluate the result under the fourth use condition, estimated by the first arithmetic unit, by comparing the result with the third evaluation data stored in the second storage unit. When the above evaluation by comparison is performed, for example, a user is able to objectively ensure the validity of estimation made by the system under a plurality of use conditions.

A second aspect of the disclosure is implemented as a method of estimating a result of an endurance test on a fuel cell system. The method includes causing a first storage unit to store a result of the endurance test actually carried out over a first period under a first use condition as training data, and causing a machine learning model, configured to perform machine learning using the training data stored in the first storage unit and included in a first arithmetic unit, to estimate a result when the endurance test is carried out under a second use condition. In this case, the first use condition may be a use condition in which a predetermined operation parameter that influences degradation of the fuel cell system appears with equal frequency over an entire domain of the operation parameter. The second use condition may be a use condition in which the operation parameter appears with unequal frequency in at least part of the domain. With the above configuration, regardless of the details of the second use condition, that is, regardless of a use condition that the fuel cell system experiences, the durability of the fuel cell system is estimated.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a block diagram that shows the configuration of an estimation system according to a first embodiment;

FIG. 2 is a view that shows an endurance test time for which an endurance test has been carried out under each use condition;

FIG. 3 is a graph that shows an accumulated time (t) for a current (I) under an equal frequency use condition;

FIG. 4 is a graph that shows an accumulated time (t) for a current (I) under a first product use condition;

FIG. 5 is a graph that shows an accumulated time (t) for a current (I) under a second product use condition;

FIG. 6 is a graph that shows an accumulated time (t) for a current (I) under a third product use condition;

FIG. 7 is a graph that shows an accumulated time (t) for a current (I) under a fourth product use condition;

FIG. 8 is a diagram that illustrates a learning model of a first arithmetic unit;

FIG. 9 is a view that illustrates an equal frequency;

FIG. 10 is a graph that illustrates an equal frequency (particularly, Gini coefficient);

FIG. 11 is a flowchart that shows the procedure of an estimation method; and

FIG. 12 is a block diagram that shows the configuration of an estimation system according to a second embodiment.

### DETAILED DESCRIPTION OF EMBODIMENTS

### First Embodiment

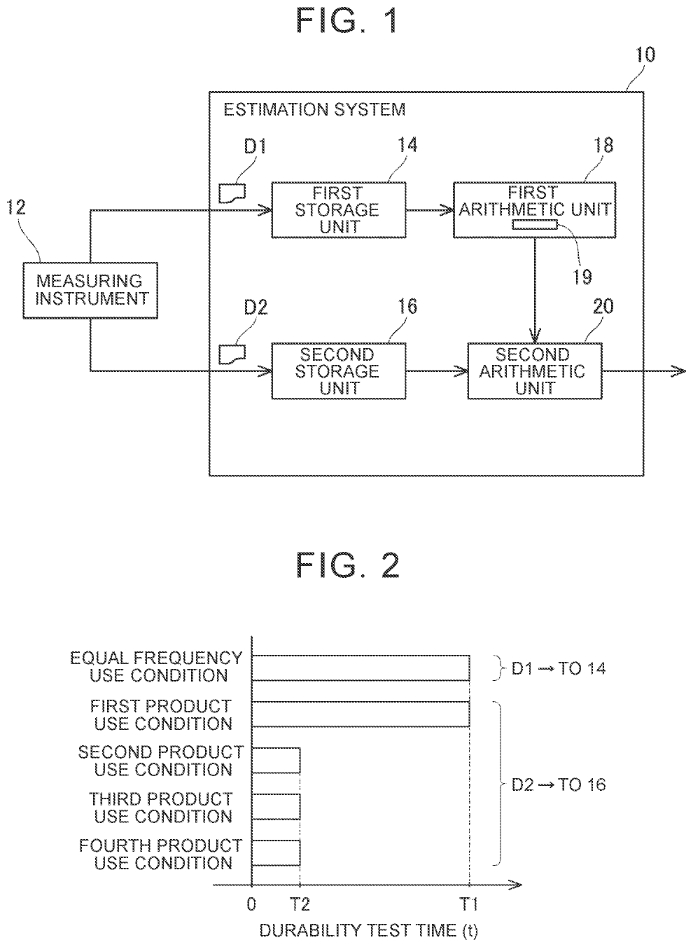

The configuration of an estimation system 10 according to the present embodiment will be described with reference to FIG. 1. The estimation system 10 estimates a result of an endurance test on a fuel cell system. For example, a fuel cell system on which the result of the endurance test is estimated by the estimation system 10 is the one mounted on a vehicle.

As shown in FIG. 1, the estimation system 10 is communicably connected to a measuring instrument 12. The measuring instrument 12 carries out an endurance test on a fuel cell system. The measuring instrument 12 acquires at predetermined time intervals values of various parameters respectively measured by sensors and stores the values of various parameters together with control signals (for example, a target current and the like) for controlling the fuel cell system as time-series data in association with time information. Various parameters here include the voltage, current, voltage speed, temperature, gas flow rate, gas pressure, and the like of the fuel cell system. The measuring instrument 12 transmits these results of the endurance test on the fuel cell system to the estimation system 10 as training data D1 and evaluation data D2.

The estimation system 10 includes a first storage unit 14, a second storage unit 16, a first arithmetic unit 18, and a second arithmetic unit 20. The first storage unit 14 is communicably connected to the measuring instrument 12 and the first arithmetic unit 18. The first storage unit 14 has a memory. The first storage unit 14 stores the training data D1 provided from the measuring instrument 12. The first storage unit 14 transmits the stored training data D1 to the first arithmetic unit 18. The second storage unit 16 is communicably connected to the measuring instrument 12 and the second arithmetic unit 20. The second storage unit 16 has a memory. The second storage unit 16 stores the evaluation data D2 provided from the measuring instrument 12. The second storage unit 16 transmits the stored evaluation data D2 to the second arithmetic unit 20.

The first arithmetic unit 18 has a memory and a CPU. The first arithmetic unit 18 causes the CPU to run various processes based on a program prestored in the memory. The first arithmetic unit 18 has a learning model 19 stored in the memory. The first arithmetic unit 18 causes the learning model 19 to perform machine learning on the training data D1 received from the first storage unit 14. The first storage unit 14 estimates the result of the endurance test on the fuel cell system by using the learning model 19. The first arithmetic unit 18 is communicably connected to the second arithmetic unit 20. The first arithmetic unit 18 transmits the result of the endurance test, estimated by the learning model 19, to the second arithmetic unit 20.

The second arithmetic unit 20 has a memory and a CPU. The second arithmetic unit 20 causes the CPU to run various processes based on a program prestored in the memory. The second arithmetic unit 20 evaluates the estimated result of the endurance test, received from the first arithmetic unit 18, by comparing the result with the evaluation data D2 received from the second storage unit 16. Specifically, the second arithmetic unit 20 outputs an error between the estimated result of the endurance test by the first arithmetic unit 18 and the evaluation data D2.

The training data D1 and the evaluation data D2 will be described with reference to FIG. 2 to FIG. 7. The result of the endurance test on the fuel cell system is influenced by use conditions (the type of a vehicle, use, use environment, and the like) that the fuel cell system experiences. In other words, depending on these use conditions, the ranges and appearance frequencies (that is, accumulated times) of values that can be taken by various operation parameters that influence the degradation of the fuel cell system (hereinafter, referred to as degradation parameters) vary. Examples of the degradation parameters include the rate of change in current, the rate of change in voltage, and ambient temperature.

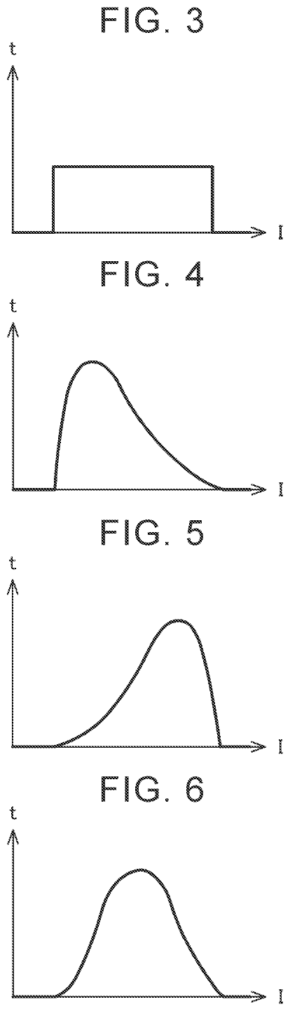

As shown in FIG. 2, the training data D1 includes endurance test data (hereinafter, simply referred to as data) under an equal frequency use condition. Data under the equal frequency use condition represents the result of the endurance test carried out over a first period (T1) under the equal frequency use condition. The first period (T1) is a period needed as a test period for the endurance test on the fuel cell system. The equal frequency use condition is a use condition that appears with equal frequency in the entire domain of each of the degradation parameters in the fuel cell system. In the equal frequency use condition, as shown in FIG. 3, for example, as for a current (I) that is one of the degradation parameters, an accumulated time (t) is equal over the entire domain of the range of possible values.

The evaluation data D2 includes pieces of data of a first product use condition, a second product use condition, a third product use condition, and a fourth product use condition. Data under the first product use condition represents the result of the endurance test carried out over the first period (T1) under the first product use condition. In the first product use condition, as for the current (I), for example, as shown in FIG. 4, the accumulated time (t) is long in a relatively low current range, and the accumulated time (t) is short in a relatively high current range. A relatively low current range means a current range in which the current (I) is lower than a half of a maximum current value of the entire domain in the range of possible values of the current (I). A relatively high current range means a current range in which the current (I) is higher than the value that is a half of the maximum current value of the entire domain of the range of possible values of the current (I).

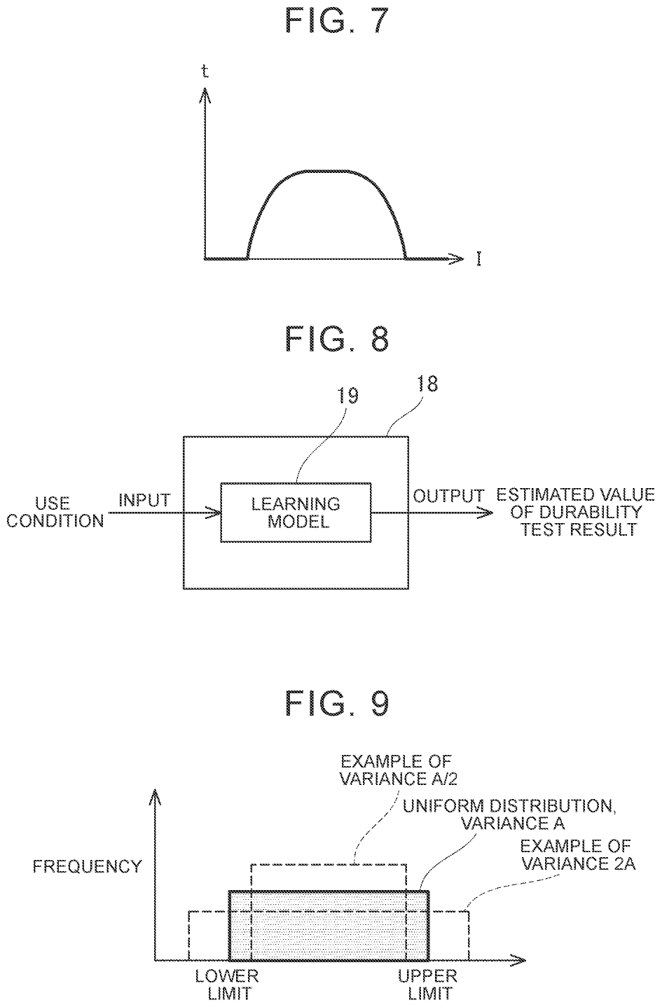

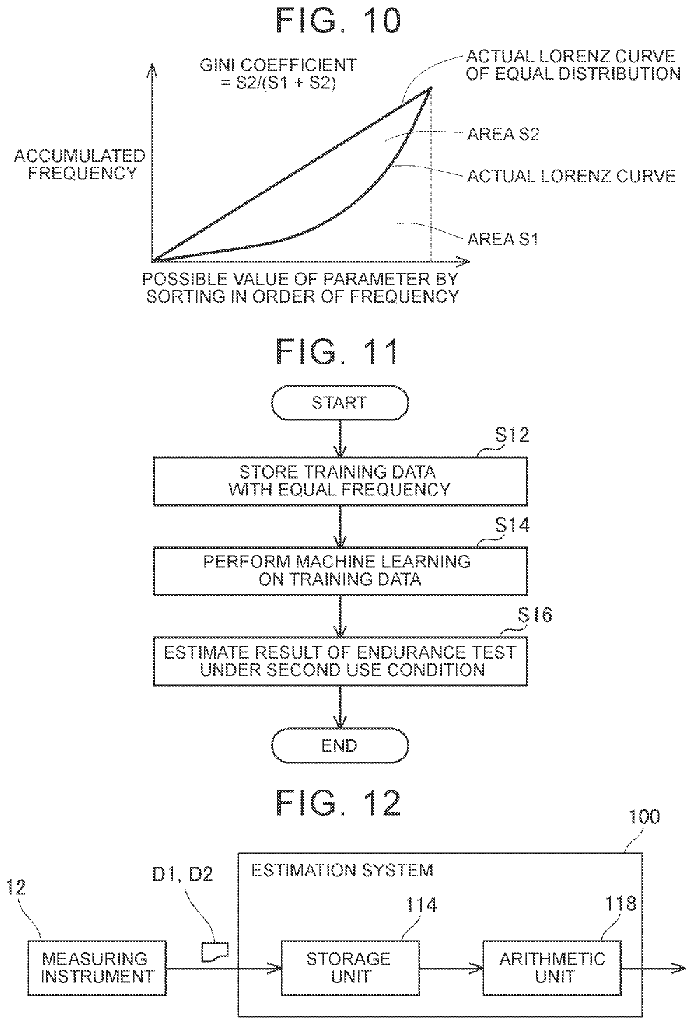

Pieces of data under the second to fourth product use conditions are results of the endurance test carried out over a second period (T2) under the second to fourth product use conditions, respectively. The second period (T2) is shorter than the first period (T1). The second period (T2) is, for example, a period that is one tenth of the first period. In the second product use condition, as for the current (I), for example, as shown in FIG. 5, the accumulated time (t) is short in a relatively low current range, and the accumulated time (t) is long in a relatively high current range. In the third product use condition, as for the current (I), for example, as shown in FIG. 6, the accumulated time (t) is the longest at a value that is a half of the maximum current value. In the fourth product use condition, as for the current (I), for example, as shown in FIG. 7, the accumulated time (t) is relatively long around a half value of the maximum current value. A distribution of the fourth product use condition has a broad distribution as compared to the first to third product use conditions.

As described above, the first to fourth product use conditions are use conditions in which degradation parameters (for example, current) appear with unequal frequency in at least part of the domain. The first, second, third, and fourth product use conditions are use conditions with appearance frequencies different from one another. Here, the phrases “equal frequency use condition”, “first product use condition”, “second product use condition”, and “third product use condition” are respectively examples of the “first use condition”, “second use condition”, “third use condition”, and “fourth use condition” in the technology of the disclosure.

The learning model 19 will be described with reference to FIG. 8. When the learning model 19 of the first arithmetic unit 18 receives a product use condition intended for estimation, for example, the second product use condition, the learning model 19 outputs an estimated value of the result of the endurance test under the second product use condition. Input parameters (use condition) include the rate of change in current value, the rate of change in temperature, the rate of change in voltage, operation time, and the like. Here, an output parameter (the result of the endurance test) is, for example, a voltage value of the fuel cell system when the current of the fuel cell system is a predetermined value. As the voltage value increases, it is determined that the durability of the fuel cell system is higher. As the voltage value decreases, it is determined that the durability of the fuel cell system is lower. The learning model 19 may be configured to, when an input use condition is given by using data of part of the training data D1 read from the first storage unit 14, be optimized such that an error between an estimated value of the output and the result of the endurance test actually carried out is minimum. To ensure the generalization performance of the learning model 19, part of the training data D1 may be reserved in the first arithmetic unit 18 for verification. In this case, the reserved data may be used to avoid over-training.

The output parameter of the learning model 19 is not limited to a voltage value at a specific current value and may be a voltage value when a specific condition is combined, such as a voltage value at a specific temperature and a specific gas supply amount. The output parameter just needs to be an index value that represents the degree of degradation of the fuel cell system. In a modification, the output parameter may be, for example, the amount of gas that leaks from a gas tank when a pressure is exerted on hydrogen in a specific condition.

In the present embodiment, ElasticNet is adopted as the learning model 19. However, the learning model 19 is not limited. A regression different from ElasticNet (for example, Ridge regression, Lasso regression, or the like) or another machine learning model, such as a neural network, may be adopted.

The second arithmetic unit 20 is capable of evaluating the result of the endurance test under the second product use condition, estimated by the learning model 19 of the first arithmetic unit 18, by comparing the result with the data under the second product use condition of the evaluation data D2 stored in the second storage unit 16. In this case, the second arithmetic unit 20 compares the estimated result of the endurance test under the second product use condition for the second period (T2), with the data under the second product use condition, actually carried out over the second period (T2), and the second arithmetic unit 20 outputs an error between the two values. Thus, a user is able to objectively ensure the validity (reliability) of estimation of the result of the endurance test by the estimation system 10 even with data in a short period. If the validity of estimation is lower than a reference value, that is, the output error is greater than a reference value, machine learning may be performed by using the result of the actual endurance test under the second product use condition, and the first arithmetic unit 18 may be caused to correct the machine learning model. Here, the error may be a mean squared error or root mean square error (RMSE). The estimation system 10 estimates the result of the endurance test under not only the second product use condition but also the first product use condition, the third product use condition, or the fourth product use condition. In this case, the estimation system 10 evaluates the estimated result of the endurance test for the second period (T2) under the same use condition, by comparing the result with data of the endurance test actually carried out over the second period (T2). When the above evaluation by comparison is performed, for example, a user is able to objectively ensure the validity of estimation made by the system under a plurality of use conditions.

The second arithmetic unit 20 estimates the result of the endurance test under the first product use condition by using the learning model 19 of the first arithmetic unit 18. Therefore, the second arithmetic unit 20 is capable of evaluating the result of the endurance test under the first product use condition, estimated by the learning model 19 of the first arithmetic unit 18, by comparing the result with the data under the first product use condition of the evaluation data D2 stored in the second storage unit 16. In this case, the second arithmetic unit 20 compares the estimated result of the endurance test under the first product use condition for the first period (T1), with the data under the first product use condition, actually carried out over the first period (T1), and the second arithmetic unit 20 outputs an error between the two values. Thus, a user is able to objectively ensure the validity (reliability) of estimation of the result of the endurance test by the estimation system 10 also in a period for which the endurance test is needed.

The estimation system 10 is capable of ensuring the validity (reliability) of estimation of the result of the endurance test under four use conditions based on the result although the period is short. Therefore, a user is able to ensure the validity of estimation using data in the first period (T1), that is, in the entire period of the endurance test, under the first product use condition from the tendency of error under the four use conditions.

Here, equal frequency will be described with reference to FIG. 11 and FIG. 12. Equal frequency in the specification is defined as that “a variance of the parameter is greater than or equal to A/2 and less than or equal to 2A where A is a variance in the case of uniform distribution in a possible domain of the parameter (working range) (Upper limit−Lower limit)\hat{ }2/12” and “the Gini coefficient of the frequency of a set in which one or more data of the value of the parameter is present in data is less than or equal to 0.5”. The former represents that the width of a change in data is the order substantially equivalent to the uniform distribution. The latter represents that possible values of the Gini coefficient range from zero to one and the state where the Gini coefficient is less than or equal to 0.5 represents that data is not unevenly distributed at a specific value. Preferably, from the viewpoint of the reliability of the result of machine learning, a use condition when a product is specified is not determined in advance, so a degradation parameter should be uniformly distributed over a domain of possible values. In this case, the variance of the parameter is A, and the Gini coefficient is zero. A variance can be any value depending on data, so the range is not determined in absolute value and should be determined so as to be close to uniform distribution as an order (digit). In other words, the range should be determined by ratio (evenly spaced by logarithm. Degradation parameters can be not designated independently of one another. For example, a current and a voltage are determined such that, when the other condition is fixed, one is determined and the other is determined in accordance with the I-V characteristics. A current and a voltage cannot be designated at selected values at the same time by means of a test condition. Particularly, when the I-V characteristics are nonlinear, it is impossible to implement a uniform distribution at the same time. In such a case, data is acquired under the condition that a frequency distribution of each parameter is equivalent in a segmented time period, and a continuum/aggregate of them may be used as training data D1.

Generally, before a new product of a vehicle is sold in a market, an endurance test on a fuel cell system to be mounted on the vehicle needs to be carried out in advance. However, if the endurance test is carried out until the service life of the fuel cell system, enormous time needs to be consumed. It is conceivable to estimate the durability of a fuel cell system by using an estimation model subjected to machine learning as one of methods of solving the above task.

However, even for the same battery, use conditions that a fuel cell system experiences vary in accordance with the type and use of a vehicle on which the fuel cell system is mounted. In other words, there are various operation parameters (for example, a rate of change in current, a rate of change in voltage, ambient temperature, and the like) in a fuel cell system, and the range and the appearance frequency of possible values of each operation parameter vary in accordance with the type and use of a vehicle on which the fuel cell system is mounted. These operation parameters influence the degradation of the fuel cell system. Therefore, in an existing idea, an estimation model subjected to machine learning needs to be individually prepared in accordance with a use condition that a fuel cell system experiences (for example, the type and use of a vehicle on which a fuel cell system is mounted).

In light of the above task, in the estimation system 10 according to the present embodiment, the result of the endurance test actually carried out under the equal frequency use condition is stored as the training data D1. Then, by performing machine learning using the training data D1, the learning model 19 configured to estimate, for example, the durability of (more specifically, the result of the endurance test on) the fuel cell system under the second product use condition is created. Under the equal frequency use condition, a predetermined degradation parameter that influences the degradation of the fuel cell system appears with equal frequency over the entire domain of the degradation parameter. By using such a result of a non-biased endurance test, the high general-purpose learning model 19 widely compatible even under various use conditions is prepared. Thus, regardless of the details of the second product use condition, that is, regardless of a use condition that the fuel cell system experiences, the durability of the fuel cell system is estimated.

Therefore, even when the use condition desired to estimate the result of the endurance test is another use condition, that is, for example, the first product use condition, the third product use condition, the fourth product use condition, or the like, instead of the second product use condition, it is possible to estimate the durability of the fuel cell system under a desired use condition.

Next, the procedure of a process of estimating (a method of estimating) durability, which the estimation system 10 executes, will be described with reference to FIG. 11. Here, it is assumed that the use condition desired to estimate the durability of the fuel cell system is a second product use condition. Initially, in step S12, the estimation system 10 executes a storage process. In the storage process, the estimation system 10 causes the first storage unit 14 to store training data D1 under the equal frequency use condition. Subsequently, in step S14, the estimation system 10 executes a machine learning process. In the machine learning process, the estimation system 10 causes the learning model 19 of the first arithmetic unit 18 to perform machine learning on the training data D1 stored in the first storage unit 14 in S12. Subsequently, in step S16, the estimation system 10 executes an estimation process. In the estimation process, the estimation system 10 causes the first arithmetic unit 18 to estimate the result of the endurance test under the second product use condition. Specifically, by inputting the second product use condition to the learning model 19, the learning model 19 is caused to output an estimated value of the result of the endurance test under the second product use condition. Through step S12, step S14, and step S16, the durability under the second product use condition is estimated.

In the estimation system 10 according to the present embodiment, the second storage unit 16 stores the results of the endurance test under four use conditions, that is, the first to fourth product use conditions. The results of the endurance test, stored in the second storage unit 16, are not limited to the results of the endurance test under four use conditions and may be the results of the endurance test under two, three, or five or more use conditions. Preferably, as the number of the results of the endurance test increases, the validity of estimation is more correctly verified. As the period of the endurance test of the result of the endurance test actually carried out approaches the first period (T1), the validity of estimation is more correctly verified. However, even when the period of the endurance test is short, the technology is effective.

### Second Embodiment

The configuration of an estimation system 100 according to the present embodiment will be described with reference to FIG. 12. As shown in FIG. 12, the estimation system 100 includes a storage unit 114 and an arithmetic unit 118. The storage unit 114 according to the second embodiment is made up of the first storage unit 14 and the second storage unit 16 according to the first embodiment, integrated with each other. The arithmetic unit 118 according to the second embodiment is made up of the first arithmetic unit 18 and the second arithmetic unit 20 according to the first embodiment, integrated with each other. In other words, the storage unit 114 has an equivalent function to the first storage unit 14 and the second storage unit 16 according to the first embodiment, and the arithmetic unit 118 has an equivalent function to the first arithmetic unit 18 and the second arithmetic unit 20 according to the first embodiment. Therefore, the estimation system 100 according to the second embodiment is configured similarly to the estimation system 10 according to the first embodiment except that the two storage units 14, 16 according to the first embodiment are configured as an integrated unit and the two arithmetic units 18, 20 according to first embodiment are configured as an integrated unit. Thus, with the configuration of the estimation system 100 according to the present embodiment, regardless of a use condition under which the fuel cell system experiences, the durability of the fuel cell system is estimated.

A system explained in the present disclosure is a system of estimating a result of an endurance test on a fuel cell system. The system includes; a first storage unit configured to store a result of the endurance test actually carried out over a first period under a first use condition as training data, and a first arithmetic unit having a machine learning model configured to perform machine learning using the training data stored in the first storage unit, the machine learning model being configured to estimate a result when the endurance test is carried out under a second use condition. The first use condition is a use condition in which a predetermined operation parameter that influences degradation of the fuel cell system appears with equal frequency over an entire domain of the operation parameter. The second use condition is a use condition in which the operation parameter appears with unequal frequency in at least part of the domain of the operation parameter.

The system may further includes; a second storage unit configured to store a result of the endurance test actually carried out over a second period shorter than the first period under the second use condition as first evaluation data, and a second arithmetic unit configured to evaluate a result for shorter than or equal to the second period, estimated by the first arithmetic unit, by comparing the result with the first evaluation data stored in the second storage unit.

In the system, the second storage unit may be configured to store a result of the endurance test actually carried out over the first period under a third use condition as second evaluation data. The first arithmetic unit may be configured to estimate a result when the endurance test has been carried out for longer than or equal to the second period under the third use condition, by using the second evaluation data stored in the second storage unit. The second arithmetic unit may be configured to evaluate the result under the third use condition, estimated by the first arithmetic unit, by comparing the result with the second evaluation data stored in the second storage unit.

In the system, the second storage unit may be configured to store a result of the endurance test actually carried out over the second period under a fourth use condition as third evaluation data. The first arithmetic unit may be configured to estimate a result when the endurance test has been carried out for shorter than or equal to the second period under the fourth use condition, by using the third evaluation data stored in the second storage unit. The second arithmetic may be further configured to evaluate the result under the fourth use condition, estimated by the first arithmetic unit, by comparing the result with the third evaluation data stored in the second storage unit.

A method explained in the present disclosure is a method of estimating a result of an endurance test on a fuel cell system. The method includes; causing a first storage unit to store a result of the endurance test actually carried out over a first period under a first use condition as training data, and causing a machine learning model, configured to perform machine learning using the training data stored in the first storage unit and included in a first arithmetic unit, to estimate a result when the endurance test is carried out under a second use condition. The first use condition is a use condition in which a predetermined operation parameter that influences degradation of the fuel cell system appears with equal frequency over an entire domain of the operation parameter. The second use condition is a use condition in which the operation parameter appears with unequal frequency in at least part of the domain of the operation parameter.

Specific examples of the technology disclosed in the specification have been described in detail; however, these are only illustrative and are not intended to limit the scope of the appended claims. The technology described in the appended claims also encompasses various modifications and changes from the specific examples illustrated above. The technical elements described in the specification or the drawings exhibit technical usability solely or in various combinations and are not limited to combinations of the appended claims at the time of filing the application. The technology illustrated in the specification and drawings can achieve multiple purposes at the same time and has technical usability by achieving one of those purposes.

What is claimed is:

1. A system of estimating a result of an endurance test on a fuel cell system, the system comprising:
a first storage unit configured to store a result of the endurance test actually carried out over a first period under a first use condition as training data; and
a first arithmetic unit having a machine learning model configured to perform machine learning using the training data stored in the first storage unit, the machine learning model being configured to estimate a result when the endurance test is carried out under a second use condition, wherein
the first use condition is a use condition in which a predetermined operation parameter that influences degradation of the fuel cell system appears with equal frequency over an entire domain of the operation parameter, and
the second use condition is a use condition in which the operation parameter appears with unequal frequency in at least part of the domain of the operation parameter.

2. The system according to claim 1, further comprising:
a second storage unit configured to store a result of the endurance test actually carried out over a second period shorter than the first period under the second use condition as first evaluation data; and
a second arithmetic unit configured to evaluate a result for shorter than or equal to the second period, estimated by the first arithmetic unit, by comparing the result with the first evaluation data stored in the second storage unit.

3. The system according to claim 2, wherein:
the second storage unit is further configured to store a result of the endurance test actually carried out over the first period under a third use condition as second evaluation data,
the first arithmetic unit is further configured to estimate a result when the endurance test has been carried out for longer than or equal to the second period under the third use condition, by using the second evaluation data stored in the second storage unit, and
the second arithmetic unit is further configured to evaluate the result under the third use condition, estimated by the first arithmetic unit, by comparing the result with the second evaluation data stored in the second storage unit.

4. The system according to claim 3, wherein:
the second storage unit is further configured to store a result of the endurance test actually carried out over the second period under a fourth use condition as third evaluation data;
the first arithmetic unit is further configured to estimate a result when the endurance test has been carried out for shorter than or equal to the second period under the fourth use condition, by using the third evaluation data stored in the second storage unit; and
the second arithmetic unit is further configured to evaluate the result under the fourth use condition, estimated by the first arithmetic unit, by comparing the result with the third evaluation data stored in the second storage unit.

5. A method of estimating a result of an endurance test on a fuel cell system, the method comprising:
causing a first storage unit to store a result of the endurance test actually carried out over a first period under a first use condition as training data; and
causing a machine learning model, configured to perform machine learning using the training data stored in the first storage unit and included in a first arithmetic unit, to estimate a result when the endurance test is carried out under a second use condition, wherein:
the first use condition is a use condition in which a predetermined operation parameter that influences degradation of the fuel cell system appears with equal frequency over an entire domain of the operation parameter; and
the second use condition is a use condition in which the operation parameter appears with unequal frequency in at least part of the domain of the operation parameter.
